(19) United States
(12) Patent Application Publication
(10) Pub. No.: US 2020/0033393 A1
(43) Pub. Date: Jan. 30, 2020

(54) ELECTRICAL TRANSMISSION LINE SENSING

(71) Applicant: Andium Inc., New York, NY (US)

(72) Inventors: Jory Schwach, New York, NY (US); Rongkai Xu, Holmdel, NJ (US)

(21) Appl. No.: 16/337,276

(22) PCT Filed: Sep. 28, 2017
(86) PCT No.: PCT/US17/53860

§ 371 Date: Mar. 27, 2019

Related U.S. Application Data
(60) Provisional application No. 62/401,081, filed on Sep. 28, 2016.

(51) Int. Cl. G01R 31/08; G01R 15/20

(52) U.S. Cl. CPC G01R 31/085; G01R 15/202; G01R 31/088

(57) ABSTRACT

Various embodiments of the present disclosure include a method for monitoring an electrical transmission line. The method can include generating a signal with a magnetometer in response to receipt of an electrical field generated by the electrical transmission line with the magnetometer, wherein the magnetometer is included in a first node disposed at a first location located adjacent to the electrical transmission line. The method can include analyzing the signal in relation to a health status associated with the electrical transmission line. The method can include relaying the indication of the health status to a central server via a second node that is disposed at a second location located adjacent to the electrical transmission line and down the electrical transmission line.

### BACKGROUND

### a. Field

The instant disclosure relates generally to electrical transmission line sensing.

### b. Background

When a power line fails, utility companies are often left scrambling to locate the point of failure, ultimately costing themselves and other affected companies billions in lost revenues. Solutions are beginning to emerge that help with locating these failure points, as well as providing other power quality measures (e.g. power surges, spikes, frequency shifts, etc.) to help utility companies diagnose, locate and fix emerging power line issues. However, the existing solutions are cumbersome (and often dangerous) to implement, incapable of sending real-time alerts and virtually impossible to integrate with other solutions when using different vendors.

### BRIEF SUMMARY

Various embodiments of the present disclosure include a method for monitoring an electrical transmission line. The method can include generating a signal with a magnetometer in response to receipt of an electrical field generated by the electrical transmission line with the magnetometer, wherein the magnetometer is included in a first node disposed at a first location located adjacent to the electrical transmission line. The method can include analyzing the signal in relation to a health status associated with the electrical transmission line. The method can include relaying the indication of the health status to a central server via a second node that is disposed at a second location located adjacent to the electrical transmission line and down the electrical transmission line.

Various embodiments of the present disclosure include a method for monitoring an electrical transmission line. The method can include generating a signal with a magnetometer in response to receipt of an electrical field generated by the electrical transmission line with the magnetometer, wherein the magnetometer is included in a first node disposed at a first location located adjacent to the electrical transmission line. The method can include detecting a change in magnitude of the electrical field, based on the signal. The method can include relaying an indication of the change in magnitude of the electrical field to a central computing device via a second node that is disposed at a second location located adjacent to the electrical transmission line and down the electrical transmission line. The method can include analyzing the signal at the central computing device to determine a health status of the electrical transmission line.

Various embodiments of the present disclosure can include a system for monitoring an electrical transmission line. The system can include a plurality of nodes disposed adjacent to and along the electrical transmission line, wherein each node includes a magnetometer configured to generate a signal in response to receipt of an electrical field generated by the electrical transmission line with the magnetometer; a wireless communication interface configured to allow for communication between neighboring ones of the plurality of nodes; and a processor and memory configured to analyze the signal in relation to a health status associated with the electrical transmission line. The system can include a central computing device configured to receive the health status from one of the plurality of nodes; and generate a notification via the central computing device in response to the determination of the health status of the electrical transmission line.

### BRIEF DESCRIPTION OF THE DRAWINGS

FIGS. 1A to 1B depict a transition from a centralized power source to a decentralized power exchange, in accordance with embodiments of the present disclosure.

FIG. 2 depicts a current transformer (CT) powered device, in accordance with embodiments of the present disclosure.

FIG. 3 is a graph that indicates a magnetic field produced by an overhead transmission line versus a distance from a centerline of the transmission line, in accordance with embodiments of the present disclosure.

FIG. 4 is a graph that indicates a magnetic field produced by an underground transmission line versus a distance from a centerline of the transmission line, in accordance with embodiments of the present disclosure.

FIG. 5 depicts a circuit for measuring a magnetic field produced by an overhead or underground transmission line, in accordance with embodiments of the present disclosure.

FIG. 6 depicts an electromagnetic field (EMF) indicator circuit, in accordance with embodiments of the present disclosure.

FIG. 7 depicts a diagram of an example of a computing device, according to various embodiments of the present disclosure.

### DETAILED DESCRIPTION

Various embodiments of the present disclosure can include at least one of a method, apparatus, and/or system for electrical transmission line sensing. The Internet of Things (IoT) is causing a significant change in the utilities industry. The industry is opting for intelligent assets, grids, meters, and appliances to enhance the interaction between assets, products, and people. Embodiments of the present disclosure can provide a smart grid platform/system that can provide benefits associated with power line failure monitoring and notification. There are numerous potential applications based on IoT that can benefit the whole energy sector. Some embodiments of the present disclosure can provide a line fault locator and/or security (e.g., security monitoring) associated with transmission lines. Some embodiments of the present disclosure can monitor a status associated with an electrical source (e.g., transmission line, utility equipment). In an example, embodiments of the present disclosure are not limited to monitoring a status associated with electrical transmission lines. For instance, embodiments of the present disclosure can be used to monitor utility equipment, such as water meters, flow meters, etc., which emit an electromagnetic field from a magnetic dial that is used. The electromagnetic field can be analyzed and a determination of an amount of water passing through the meter (e.g., water meter) can be determined. For instance, as the magnetic dial spins faster a greater magnetic field will be generated, which can be analyzed to determine the amount of water passing through the meter.

Some embodiments of the present disclosure can provide a Hall Effect sensor and/or MilliGaussian sensor grid monitoring system that can provide a low cost and long range IoT solution to reshape the power industry. Embodiments of the present disclosure can include a faulty line detection and power quality metering solution that provides real-time remote detection of power line failures. Through its ability to diagnose and locate points of failure in real-time, embodiments of the present disclosure can allow utility companies the ability to respond and repair issues much more efficiently, saving precious time and money.

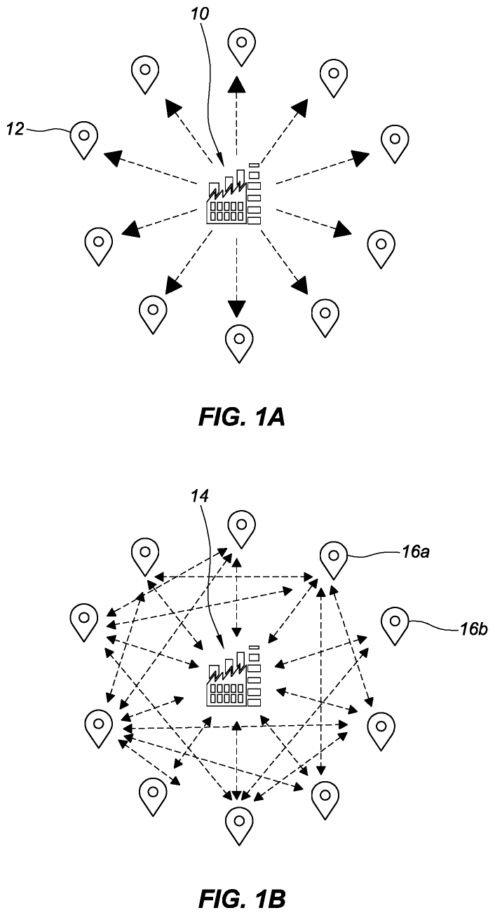

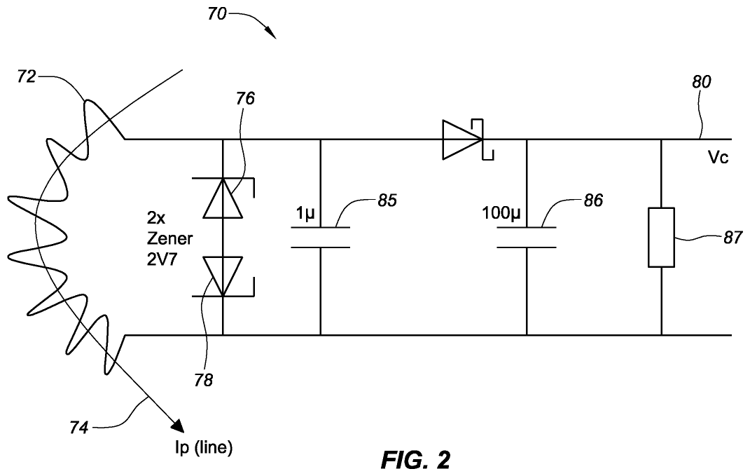

FIGS. 1A to 1B depict a transition from a centralized power source to a decentralized power exchange, in accordance with embodiments of the present disclosure. As depicted in FIG. 1A, some power sources 10 are arranged in a centralized fashion where each of a series of nodes (e.g., node 12) has a direct communication link to the centralized power source (e.g., service center associated with a power source). This can create great difficulties in terms of creating an uninterrupted communication link from each node 10 to the centralized power source. The energy industry is experiencing a new revolution due to the great advances in terms of remote sensing, real-time monitoring, machine-to-machine communication and cloud computing and storage. Embodiments of the present disclosure include transition from a centralized layout to a decentralized one, as depicted in FIG. 1B. In an example, each of a series of nodes (e.g., nodes 16a, 16b), as discussed herein can be in communication with one another and with a power source 14. For instance, the nodes 16a, 16b can be in communication with the power source 14, but also in communication with one another and with one or more other nodes in a network of nodes. This can enable one or more nodes in the network to pass messages to one another and relay messages from one another to the power source 14, without there having to be an individualized communication link specific to each one of the nodes in the network.

When a power line fails, utility companies are often left scrambling to locate the point of failure, ultimately costing themselves and other affected companies billions in lost revenues. Solutions are beginning to emerge that help with locating these failure points, as well as providing other power quality measures (e.g. measures of power surges, spikes, etc.), also referred to herein as health status, to help utility companies diagnose, locate and fix emerging power line issues. However, the existing solutions are cumbersome (and often dangerous) to implement, incapable of sending real-time alerts and virtually impossible to integrate with other solutions when using different vendors.

With embodiments of the present disclosure, a customer can simply deploy easy-to-install, low-power, wireless devices equipped to measure power quality indicators and detect power line failures in real-time. Embodiments of the present disclosure can provide advanced service-based power monitoring solution, lowering implementation costs and ensuring quick response times.

An advanced, zero-configuration communication feature can send measurements and alerts miles away, limiting the number of required devices. Optional global positioning system (GPS) sensors also allow the devices to self-locate, providing even more accurate location information. Multiple network transmissions ensure that messages are always received, including visible alerts at failure points, text message alerts to field staff, and system alerts to centralized control centers. An advanced mesh networking can also be deployed for redundant network stability and possesses the capability to use LTE as an additional communication backup. Our visible and wireless communication is completely secure, ensuring full NERC CIP compliance. Embodiments of the present disclosure can provide user identification controls and authorized user receipts for information received, allowing utility companies to stay compliant with contractual obligations between different entities.

In addition to real-time power failure alerts, system sensitivity will allow for more nuanced power quality measurements, ranging from power surges to transients, helping utility companies identify, diagnose and prevent future failures. Unlike current stagnant solutions, embodiments of the present disclosure can provide for updates to all of the network devices, so as more information is collected, future diagnostic and testing tools can be deployed based on learnings gleaned over time. Embodiments of the present disclosure can be deployed in a residential setting (e.g., water meters) and with respect to below ground lines.

Some embodiments of the present disclosure can include a line fault locator. Remote monitoring can be difficult and expensive using current technologies to monitor overhead grids and/or underground grids. A fault in one of these grids may cost time and a lot of money to locate, diagnose and repair. Some approaches have developed equipment for monitoring the grids (e.g., underground cable fault locating), however, the equipment is very costly and is time consuming to use, requiring equipment and staff setups and also requiring highly skilled technicians to diagnose and locate the faults.

Embodiments of the present disclosure can quickly and cost effectively locate a fault. Some embodiments include a device (e.g., module, node) that is powered by a current transformer (CT). In an example, the device can be powered without use of a battery. Most of the time the device can be in deep sleep mode, unless there is a pre-defined triggered event to wake it up.

In some embodiments, the device can use an inexpensive Hall Effect and/or MilliGaussian sensor on a front analog end. In an example, the device can be one of a plurality of nodes disposed at a base of or adjacent to an electrical transmission line. For instance, the node can be attached to a base of a pole that supports the electrical transmission line and/or at a location that is located in an electrical field produced by the electrical transmission line. An edge device (a cell phone or a computer) can tag the accurate GPS location to the low-cost sensor device (e.g., node). For example, upon installation or at a later time, an edge device, equipped with a GPS sensor and/or a means for entering a GPS location can communicate with the node via a wired or wireless connection and can associate the GPS location with the node. In some embodiments, a real-time triggering event can be relayed to a cloud network, which can generate real-time messages (e.g., text messages), which can be sent to maintenance staff, as further discussed herein.

In some embodiments, a meshing network can be employed that allows all of the devices to communicate and can involve zero network configuration to set up the meshing network. In some embodiments, the device can include a highly secured system design that is in compliance with the North American Electric Reliability Corporation Critical Infrastructure Protection (NERC CIP).

Embodiments of the present disclosure can provide a very cost effective and rugged weather proof enclosure design for easy installation. The enclosure can house some or all of the componentry associated with the design (e.g., Hall Effect sensor, GPS, etc.).

FIG. 2 depicts a CT powered device 70, in accordance with embodiments of the present disclosure. In some embodiments, the CT powered device 70 can be included in a node, as discussed herein. The CT powered device 70 can provide power to the node to operate and determine power quality measurements. Embodiments of the present disclosure can be CT powered and can have a low energy consumption. The CT powered device 70 can include an energy harvester (e.g., electrical transmission line powered energy harvester, energy harvester), also referred to herein as device. As depicted in FIG. 2, the following circuitry concept can use a second, low-cost 50/60 Hz CT 72 as an external current source, although the CT 72 can be of a lower or higher frequency. For example, a power source 74 (e.g., electrical transmission line can provide power to the CT 72 via an electrical field generated by the power source 74. In some embodiments, the power source 74 can be located adjacent to the CT 72 and in some embodiments, the power source 74 can pass through a lumen formed by coils of the CT 72. In some embodiments, one or more diodes 76, 78 can be in series with the CT 72. The diodes 76, 78 can clamp the transient voltage and protect the circuit associated with the energy harvester. In an example, the diodes 76, 78 can be Zener 2V7 diodes, although embodiments are not so limited. In some embodiments, the line powered energy harvester can include a burden resistor 87 to convert it into a voltage (V_{C}) 80, a voltage limiter, a rectifier circuit and some additional components to generate a continuous, filtered output voltage between about 2.5V to 5V to power a microprocessor and transmitter module associated with the device/node when the primary current exceeds about 0.7 A.

In some embodiments, software algorithms can intelligently control the charge-pump during the charge and transfer periods. One or more models (e.g., algorithms) can match the thermoelectric device output impedance to the boost converter interface electronics to maximize the energy transfer and efficiency. For example, in some embodiments, a feedback loop can be implemented. A model (e.g., algorithm) can control the feedback loop to make sure that power consumption matches front-end inputs. An on-board analog to digital converter can sample the harvesting device voltage to determine the mode of operation. For example, the CT powered device can include one or more modes of operation in some embodiments. During unfavorable harvesting conditions (e.g., where a spike in voltage occurs and/or a voltage associated with an energy transmission line drops below a determined amount), the microprocessor can be placed into deep-sleep mode and the quiescent current can be less than 2 μA.

Some embodiments of the present disclosure can include a processor that is powered by the CT powered device. In some embodiments, an embedded microprocessor can be in a deep sleep (hibernation) mode for normal operation. For example, the node as discussed herein can include a microprocessor and the CT powered device, which in some embodiments can power the node and the microprocessor associated with the node. In some embodiments, the microprocessor can be an embedded microprocessor. The embedded microprocessor can wake up periodically to check the neighboring mesh information and check for beacon signals (alert signals).

For example, in some embodiments, a plurality of nodes can be disposed along an electrical transmission line and can be in communication with one another via a mesh network. In some embodiments, each one of the nodes can monitor the electrical field associated with the electrical transmission line located adjacent to each one of the respective nodes. For example, as discussed herein, the node can include a sensor that can be configured to measure the electrical field that is produced by the electrical transmission line. Each one of the nodes can be in communication with one or more of the other nodes included in the mesh network and can broadcast messages to one another. In some embodiments, a message can be transmitted from a first node to a second node, which can be located further down the electrical transmission line. The second node can rebroadcast the message to a third node, which is located further down the electrical transmission line from the first node and the second node. The message can be rebroadcast via a series of additional nodes located along the electrical transmission line. In some embodiments, one or more of the nodes can be in communication with a server (e.g., central computing device), which can be located at a service center and/or can be configured to rebroadcast the message to a mobile device (e.g., cell phone, etc.). In some embodiments, the embedded processor in the node can draw a very low current in sleep mode and can use 6LoWPan based MQTT protocols to realize large self-healing meshing capabilities to enable communication with neighboring nodes.

In some embodiments, as discussed herein, the node can include an electrical field sensor to enable measuring of characteristics associated with power flowing through the electrical transmission lines. In an example, some embodiments of the present disclosure can include a Hall Effect and/or milliGaussian sensor. The sensor can be an inexpensive electromagnetic field (EMF) sensor. A sensor circuit can be based on Hall effects or one or more inductive sensors and one or more comparator circuits to feed the trigger signal into the microprocessor's interrupt pin. When the microprocessor is triggered and enters into interrupt via the interrupt pin, it can wake up and send an encrypted beacon signal along with its own GPS information, etc. to its neighboring nodes. In some embodiments, the encrypted beacon signal can be sent via a long range radio and/or Bluetooth to neighboring nodes.

Some embodiments of the present disclosure can include a real-time triggering relayed to cloud. In an example, one or more capacitors 85, 86 can hold the voltage generated by the device 70 and the CT 72 for a particular time when the power source 74 (e.g., transmission line) is down until the module transmits its essential information out (e.g., to the cloud). The essential information can include, for example, location information such as GPS location information tagged by a cell phone at an installation stage. In some embodiments, the essential information can include a characteristics associated with the electrical field, which can be used to determine a type of event that has occurred in relation to the flow of power through the electrical transmission lines and/or a health status of the electrical transmission lines. For instance, a determination can be made of how much power is flowing through the electrical transmission lines based on the electrical field detected by the sensor. Thus, a determination can be made with respect to a problem occurring with the electrical transmission lines, such as a power outage, a spike in electricity flowing through the electrical transmission lines, and/or another type of event that involves the modulation of electrical energy flowing through the electrical transmission lines. In some embodiments, a change in magnitude of the electrical field can be determined based on the signal. In some embodiments, an indication of the health status can be related to the central server via a plurality of nodes disposed along the electrical transmission line, as discussed herein, in response to a magnitude of the electrical field generated by the electrical transmission line decreasing. In some embodiments, an indication of the health status can be relayed to the central server via a plurality of nodes disposed along the electrical transmission line, as discussed herein, in response to a magnitude of the electrical field generated by the electrical transmission line decreasing to a zero or near zero magnitude.

In some embodiments, neighboring devices (e.g., nodes) can wake up in response to beacon messages received from a neighboring device. The neighboring devices can pass along the beacon message to another neighboring device. In some embodiments, a model can control the relay of the beacon messages. Eventually, the beacon message can be passed to a central database and trigger an alert message to corresponding staff. For instance, a message can be passed along a network (e.g., line) of devices until the message is delivered to the central database.

As discussed, in some embodiments, long range radio frequencies can be used as a carrier frequency to exchange data between nodes and to make sure it covers enough nodes over a certain meshing area. In some embodiments, a range of the long range radio frequencies can be in a range of up to several miles, for example, in a range from 1 to 6 miles. There is a redundancy node design as a backup to make sure the system up time and accuracy is close to 100%. For example, in some embodiments, a first node can broadcast a message to more than one neighboring node. For instance, a first node can broadcast a message to more than one neighboring node that is disposed along a line of electrical transmission poles. Thus, if one of the nodes that is desired to receive the message is not operational, an adjacent node to the node that is not operational can receive the message and continue broadcasting the message to neighboring nodes, thereby providing a redundancy with regard to broadcasting the message.

In some embodiments, an edge device can tag the device (e.g., node) with information, such as location information. In some embodiments, to save costs associated with the node, rather than building a GPS module into the node, the GPS information can be passed and written into the node by an edge device, such as cell phone or laptop during initial installation. In some embodiments, as discussed herein, each node can include a computer readable medium (CRM) (e.g., non-volatile random-access memory (NVRAM), in which the GPS information can be stored. Once written into the node's NVRAM, the GPS information can be included in a part of the critical beacon messages passing to the cloud. In some embodiments, each device can include its own processor and memory. In an example, embodiments of the present disclosure can employ distributed sensors. Each sensor can be housed on an individual device that includes a microprocessor and/or memory. An algorithm is executed at each sensor node and alerts/info may only be sent out whenever there is an event.

In some embodiments, the network of devices (e.g. nodes) can be a part of a network associated with minimal and/or zero configuration. In an example, the network can rely on 6LoWPAN technology. The 6LoWPAN protocol is IP based, which can facilitate the integration into an existing network. Each component of the system, sensor node for this case, can have its own IP address, and can be interconnected with several devices in a wireless fashion.

The setup of the network system of nodes can be divided into three main parts: the central server, the border-routers (edge device, optional) and the embedded nodes. In an example, the boarder routers (edge device) can provide a communication path to the embedded nodes from the central server, in some embodiments. Some embodiments of the present disclosure can allow users to deploy the sensor nodes with minimum configuration. This means that a node should be able to enter the network automatically and inform the server with information like its address or which resources these nodes will make available.

Some embodiments of the present disclosure can include a highly secured Network. NERC includes published security guidelines for the energy (e.g., electricity) sector, especially for Critical Infrastructure Protection (CIP) and cyber security regulations for the energy sector. Embodiments of the present disclosure can exceed these requirements. In an example, hardware identification and software encryption can make sure that the data acquired is 100% safe and only accessible to authorized users. This meets or exceeds the CIP regulation CIP-004-5.1. Even if one of the devices (e.g., nodes) were hacked into, the damage would only be limited to that one hacked node.

In some embodiments, variations in an EMF field produced by a transmission line can be sensed and a determination can be made regarding a status (e.g., health status) of the transmission line. For example, a determination can be made regarding whether or not power is flowing through the line and in some embodiments, a determination regarding an amount of power flowing through the line can be made. In some embodiments, determination of the health status can include determining an amount of sag associated with the transmission line, as discussed herein. In some embodiments, the variations in the EMF field can be detected via a Hall effect sensor. In some embodiments, an EMF meter can be used to measure an EMF field strength in milliGauss.

The following table shows a feasibility of using a Hall-effect sensor as a detector for detecting surrounding electromagnetic field changes.

| | | Hall Sensor 1 Analog | Hall Sensor 2 Analog |
|---|---|---|---|
| EMF Field Strength | | Output | Output (opposite polarity) |
| 0 | mG | 1.3433 V | 1.5912 V |
| 12 | mG | 1.3441 V | 1.6005 V |

A 3.3 volt direct current power supply was used to pass electricity though a line. The power supply was switched off and produced an EMF field strength of 0 milliGauss. A first Hall sensor with an analog output measured a voltage of 1.3433 volts. When the power supply was turned on, the EMF field strength was 12 milliGauss and the first Hall sensor measured a voltage of 1.3441 volts, which is an increase over the initial voltage of 1.3433 volts. Accordingly, an analysis can be made, based on this increase to determine the amount of power flowing through the line. A second Hall sensor with an analog output using opposite polarity measured a voltage of 1.5912 volts when the power supply was turned off. When the power supply was turned on, the EMF field strength was 12 milliGauss and the second Hall sensor measured a voltage of 1.6005 volts, which is an increase over the initial voltage of 1.5912 volts. Accordingly, an analysis can be made, based on this increase to determine the amount of power flowing through the line.

Some embodiments can be used for power line signal detection for both high-voltage transmission lines and low-voltage residential power lines. Some embodiments can provide a low cost power quality indicator. Some embodiments can provide for an underground power cable cutoff detection and alert. Some embodiments can provide for a clip on installation and self-powered (battery free) IoT device. Some embodiments can provide for a long range radio to transmit information to the cloud network. Some embodiments can provide for a handheld instrument to locate the power line faults. For example, the handheld instrument can be used by a user to assess a health of an overhead power line and/or underground power line. The user can use the handheld instrument to approach a power line to obtain a reading of an electrical field associated with the power line. In some embodiments, the user can walk along a location of the power line and the electrical field can be sensed. Based on a reading associated with the electrical field, a break or other health status associated with the power line can be determined. For example, where there is a break (e.g., cut) in the power line, the electrical field can decrease in that location. In some embodiments, an indication can be provided to a user of the health of the power line.

The following chart illustrates the benefits of an IoT Hall sensor over a traditional testing system.

| | Our Hall Effect/mG | |
|---|---|---|
| | Sensor as described | |
| | in the present | |
| | disclosure | Traditional Solution |
| Cost | Extremely low | Very expensive |
| Deployment | Easy and cheap | Difficult and costly |
| Alerting | Real time | Nonexistent |
| Locating the fault | Real time | Long man hours |
| Locating the | Real time | Long man hours plus |
| underground | | expensive equipment |
| fault | | |
| Power quality | Possible | $10k plus equipment is |
| monitoring | | needed and special trained |
| | | technicians |
| System Integration | Easy | Very difficult if using |
| | | different vendors |

Some embodiments of the present disclosure can measure a magnetic field generated by a transmission line, regardless of whether it is an above ground transmission line or a below ground transmission line.

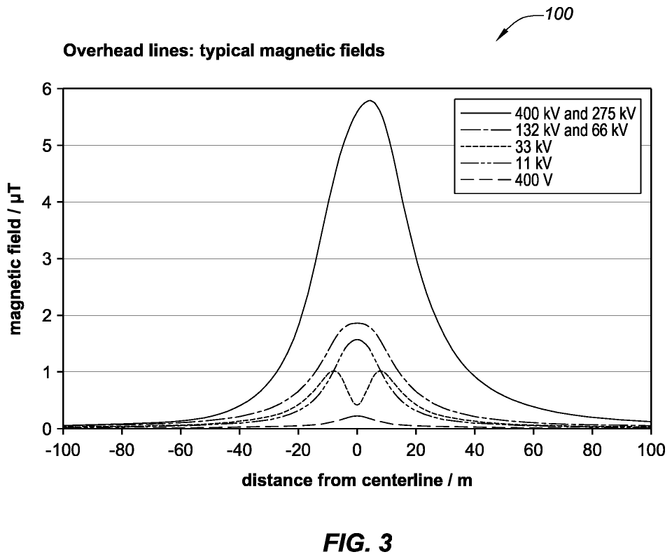

FIG. 3 depicts a graph 100 that indicates a magnetic field produced by an overhead transmission line versus a distance from a centerline of the transmission line, in accordance with embodiments of the present disclosure. Accordingly, a sufficient magnetic field is produced by the overhead transmission line to enable sensing of the magnetic field and determination of a health status of the overhead transmission line based on the magnetic field. This graph 100 depicts the magnetic field strength versus distance. As depicted, the magnetic field strength is dependent on at least distance, which provides the ability to monitor power quality using embodiments of the present disclosure. For example, at the same measuring position, if a power sag (e.g., sag in the power lines and/or drop in power running through the lines) happens, our device will sense the magnetic field change. An ideal location to place the node depends on the power transmission line rated voltages. The lower of the rated voltage, the closer we need to place our node for sensing.

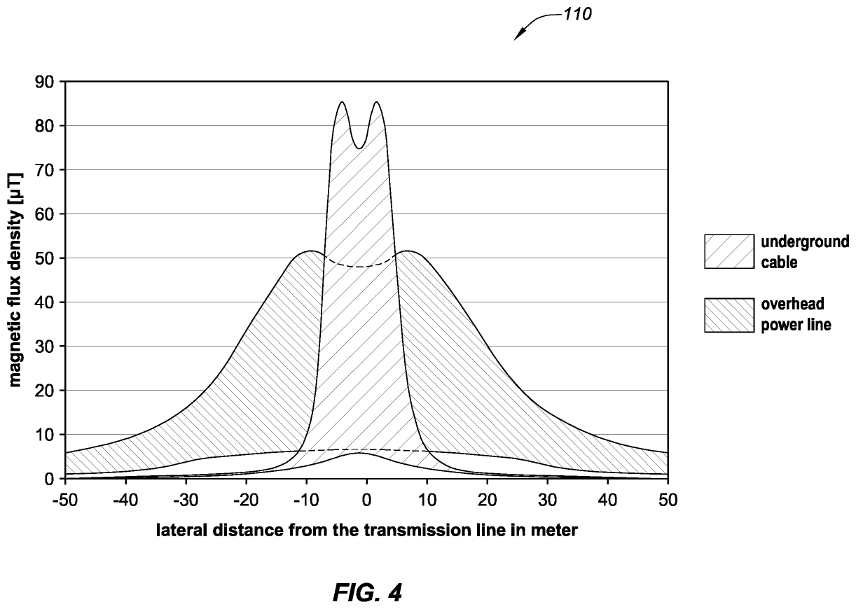

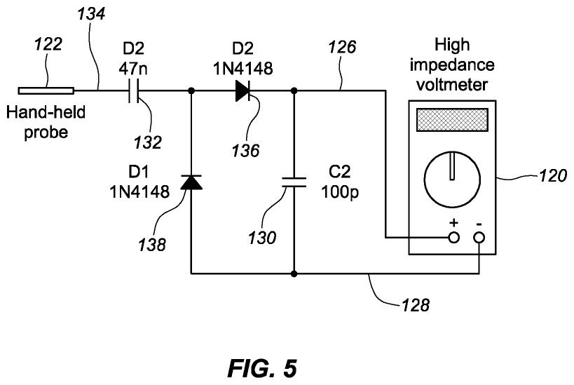

FIG. 4 depicts a graph 110 that indicates a magnetic field produced by an underground transmission line versus a distance from the transmission line, in accordance with embodiments of the present disclosure. Accordingly, a sufficient magnetic field is produced by the underground transmission line to enable sensing of the magnetic field and determination of a health status of the underground transmission line based on the magnetic field. Some embodiments of the present disclosure can employ a circuit, as depicted in FIG. 5 to measure a magnetic field produced by an overhead or underground transmission line, which depicts a possible handheld detector design.

FIG. 5 depicts a circuit for measuring a magnetic field produced by an overhead or underground transmission line, in accordance with embodiments of the present disclosure. The circuit can include a voltmeter 120, which can be in communication with a probe 122. In an example, the voltmeter can be a high impedance voltmeter, in some embodiments. In some embodiments, the probe 122 can be a hand-held probe and can include an EMF sensor, which can be configured to sense a magnetic field associated with a transmission line (e.g., overhead transmission line and/or underground transmission line. In some embodiments, the probe 122 can be electrically coupled with the voltmeter 120 via a circuit that includes a capacitor. In an example, a positive voltage input line 126 can be electrically coupled to the voltmeter 120 and a negative voltage input line 128 can be electrically coupled to the voltmeter 120. A first capacitor 130 can be coupled between the positive voltage input line 126 and the negative voltage input line 128. A second capacitor 132 can be disposed on a probe output line 134. A first diode 136 can be disposed between second capacitor 132 and the positive voltage input line 126 and a second diode 138 can be disposed between the second capacitor 132 and the negative voltage input line 128. In some embodiments, the probe 122 can sense a magnetic field associated with the transmission line and a signal can be received by the voltmeter 120 from the probe 122. The voltmeter 120 can analyze the signal to determine a voltage associated with the signal received from the probe 122 and a determination can be made, based on the voltage, regarding a health status of the transmission line (e.g., an amount of power flowing through the transmission line). In some embodiments, the voltmeter 120 can be in communication with and/or can include one or more communication components to enable the voltmeter 120 to communicate with other voltmeters. For example, the voltmeter 120 can include a processor, memory, and/or a communication radio to enable the voltmeter 120 to transmit a signal (e.g., message) to other neighboring voltmeters (e.g., nodes), as discussed herein.

In some embodiments, the capacitors 130, 132 can be configured to retain energy that is harvested via the probe 122 and/or a current transformer. In some embodiments, the probe 122 can include a coil that harvests the electromagnetic field produced by the transmission line. The energy harvested from the electromagnetic field can be stored within the capacitors 130, 132 in some embodiments, which can provide power for one or more components associated with the voltmeter 120 to function. In some embodiments, the capacitors 130, 132 can store energy for running the processor, memory, and/or communication radio.

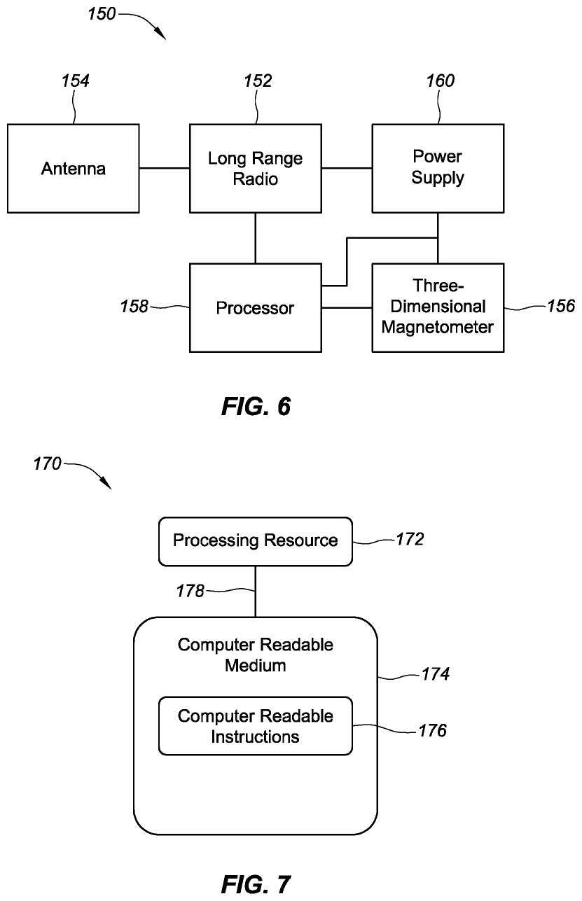

FIG. 6 depicts an EMF indicator circuit 150, in accordance with embodiments of the present disclosure. In some embodiments, the EMF indicator circuit can be included in a node and can include a long range radio 152 for broadcasting information and an antenna 154 for receiving information, which can enable the EMF indicator circuit 150 to operate in a mesh network, as discussed herein. In some embodiments, the EMF indicator circuit 150 can include a processor 158 and/or memory (not depicted), which can be in communication with the antenna 150 and the long range radio 152. The EMF indicator circuit 150 can further include a magnetometer 156, which can be in communication with the processor and a power supply 160. The magnetometer 156 can sense an electrical field and the processor 158 can analyze the signal and determine a health status of a transmission line, based on the signal from the magnetometer 156. As discussed, in some embodiments, the analysis can be performed on the node and/or on the central computing device to which the node is in communication with via neighboring nodes. In some embodiments, the magnetometer 156 can generate a signal in response to receipt of an electrical field generated by the electrical transmission line with the magnetometer 156. The magnetometer 156 can be a three-dimensional magnetometer, in some embodiments. In some embodiments, the magnetometer 156 can act as a current transformer and/or the EMF indicator circuit 150 can further include a current transformer which can harvest the electromagnetic field to charge the power supply 160. In an example, if the electromagnetic field shuts off due to an interruption with power flowing through the electrical transmission line, the power supply 160 can supply power to the EMF indicator circuit 150, such that the circuit can still transmit and/or receive data, thus ensuring it remains an operational member of a mesh network for a period of time. In some embodiments, the EMF indicator circuit can measure a magnetic flux with a granularity of 0.1 milliGauss. In some embodiments, as depicted, a magnetometer can be used to measure the EMF, however, embodiments are not so limited and other types of sensors can be used to measure the EMF. In some embodiments, the processor 158 can analyze the signal produced by the magnetometer 156 to determine a health status associated with the electrical transmission line.

In some embodiments, the magnetometer can be included in a first node, which can relay the indication of the health status to a central server via a second node that is disposed at a second location adjacent to the electrical transmission line and down the electrical transmission line. For example, a series of nodes can be placed along the electrical transmission line and at least neighboring nodes can be in communication with one another. Each one of the nodes can include a magnetometer to sense the electrical field associated with the electrical transmission line and cooperate with one another to send a health status of the electrical transmission line along the line of nodes.

In embodiments that include a three-dimensional sensor, such as a three-dimensional magnetometer, it is not only capable of detecting the overall strengths of the EMF and changes, but also capable of detecting changes in a certain axis. In some embodiments, this can aid in providing power quality analysis and fault diagnostics. For example, if an overhead transmission line is down and hanging over the tower, the EMF indicator circuit 150 can detect an increased voltage reading on an axis parallel to the tower. Accordingly, an alert indicating a fault can be broadcast to a utility company associated with the transmission line via cloud (e.g., a mesh network) and can report the power line is hanging due to the persistent high readings on axis parallel to the tower. Accordingly, embodiments of the present disclosure can detect a position of a transmission line with respect to a transmission pole that carries the transmission line and/or with respect to the EMF indicator circuit.

As discussed above, some embodiments of the present disclosure can measure a line sag associated with an above ground electrical transmission line. In some embodiments, the sensors, as discussed herein, can be placed in a fixed location with respect to the electrical transmission line. As a line sags, an increase in average voltage can be seen by the sensor as the line sags closer to the sensor. In some embodiments, a baseline measurement (e.g., EMF measurement) can be taken that indicates a standard amount of current flowing through the transmission line and/or is associated with a normal/acceptable amount of sag in the line. As a measurement deviates from the baseline measurement, an indication can be generated based on the deviation. In some embodiments, the indication can indicate a variation in current flowing through the line and/or a particular amount of sag associated with the line.

FIG. 7 depicts a diagram of an example of a computing device 170, according to various embodiments of the present disclosure. The computing device 170 can utilize software, hardware, firmware, and/or logic to perform a number of functions described herein. In an example, the computing device 170 can be representative of electronic devices depicted and discussed in relation to FIGS. 1, 5, and 6.

The computing device 170 can be a combination of hardware and instructions 176 to share information. The hardware, for example can include a processing resource 172 and/or a memory resource 174 (e.g., computer-readable medium (CRM), database, etc.). A processing resource 172, as used herein, can include a number of processors capable of executing instructions 176 stored by the memory resource 174. Processing resource 172 can be integrated in a single device or distributed across multiple devices. The instructions 176 (e.g., computer-readable instructions (CRI)) can include instructions 176 stored on the memory resource 174 and executable by the processing resource 172 to implement a desired function (e.g., debug the electronic device, as discussed in reference to FIG. 2, etc.).

The memory resource 174 can be in communication with the processing resource 172. The memory resource 174, as used herein, can include a number of memory components capable of storing instructions 176 that can be executed by the processing resource 172. Such memory resource 174 can be a non-transitory CRM. Memory resource 174 can be integrated in a single device or distributed across multiple devices. Further, memory resource 174 can be fully or partially integrated in the same device as processing resource 172 or it can be separate but accessible to that device and processing resource 172. Thus, it is noted that the computing device 170 can be implemented on a support device and/or a collection of support devices, on a mobile device and/or a collection of mobile devices, and/or a combination of the support devices and the mobile devices.

The memory resource 174 can be in communication with the processing resource 172 via a communication link 178 (e.g., path). The communication link 178 can be local or remote to a computing device associated with the processing resource 172. Examples of a local communication link 178 can include an electronic bus internal to a computing device where the memory resource 174 is one of a volatile, non-volatile, fixed, and/or removable storage medium in communication with the processing resource 172 via the electronic bus.

Link 178 (e.g., local, wide area, regional, or global network) represents a cable, wireless, fiber optic, or remote connection via a telecommunication link, an infrared link, a radio frequency link, and/or other connectors or systems that provide electronic communication. That is, the link 178 can, for example, include a link to an intranet, the Internet, or a combination of both, among other communication interfaces. The link 178 can also include intermediate proxies, for example, an intermediate proxy server (not shown), routers, switches, load balancers, and the like.

Reference throughout the specification to “various embodiments,” “some embodiments,” “one embodiment,” or “an embodiment”, or the like, means that a particular feature, structure, or characteristic described in connection with the embodiment(s) is included in at least one embodiment. Thus, appearances of the phrases “in various embodiments,” “in some embodiments,” “in one embodiment,” or “in an embodiment,” or the like, in places throughout the specification, are not necessarily all referring to the same embodiment. Furthermore, the particular features, structures, or characteristics may be combined in any suitable manner in one or more embodiments. Thus, the particular features, structures, or characteristics illustrated or described in connection with one embodiment may be combined, in whole or in part, with the features, structures, or characteristics of one or more other embodiments without limitation given that such combination is not illogical or non-functional.

Although at least one embodiment of electrical transmission line sensing has been described above with a certain degree of particularity, those skilled in the art could make numerous alterations to the disclosed embodiments without departing from the spirit or scope of this disclosure. All directional references (e.g., upper, lower, upward, downward, left, right, leftward, rightward, top, bottom, above, below, vertical, horizontal, clockwise, and counterclockwise) are only used for identification purposes to aid the reader's understanding of the present disclosure, and do not create limitations, particularly as to the position, orientation, or use of the devices. Joinder references (e.g., affixed, attached, coupled, connected, and the like) are to be construed broadly and can include intermediate members between a connection of elements and relative movement between elements. As such, joinder references do not necessarily infer that two elements are directly connected and in fixed relationship to each other. It is intended that all matter contained in the above description or shown in the accompanying drawings shall be interpreted as illustrative only and not limiting. Changes in detail or structure can be made without departing from the spirit of the disclosure as defined in the appended claims.

Any patent, publication, or other disclosure material, in whole or in part, that is said to be incorporated by reference herein is incorporated herein only to the extent that the incorporated materials does not conflict with existing definitions, statements, or other disclosure material set forth in this disclosure. As such, and to the extent necessary, the disclosure as explicitly set forth herein supersedes any conflicting material incorporated herein by reference. Any material, or portion thereof, that is said to be incorporated by reference herein, but which conflicts with existing definitions, statements, or other disclosure material set forth herein will only be incorporated to the extent that no conflict arises between that incorporated material and the existing disclosure material.

What is claimed:

1. A method for monitoring an electrical transmission line, comprising:
generating a signal with a magnetometer in response to receipt of an electrical field generated by the electrical transmission line with the magnetometer, wherein the magnetometer is included in a first node disposed at a first location located adjacent to the electrical transmission line;
analyzing the signal in relation to a health status associated with the electrical transmission line; and
relaying the indication of the health status to a central server via a second node that is disposed at a second location located adjacent to the electrical transmission line and down the electrical transmission line.

2. The method of claim 1, further comprising generating a notification in response to receipt of the indication of health status by the central server.

3. The method of claim 2, further comprising broadcasting the notification to mobile devices.

4. The method of claim 1, further comprising relaying the health status to the central server with a plurality of nodes including the second node, wherein each one of the nodes includes a magnetometer configured to monitor the electrical field generated by the electrical transmission line.

5. The method of claim 4, wherein the first node and each one of the plurality of nodes includes a current harvester configured to power each one of the nodes via conversion of the electrical field into electricity.

6. The method of claim 5, wherein each one of the nodes includes a capacitor configured to power the node in the absence of the electrical field generated by the electrical transmission line.

7. The method of claim 6, further comprising relaying the indication of the health status to the central server via the plurality of nodes in response to a magnitude of the electrical field generated by the electrical transmission line decreasing.

8. The method of claim 7, further comprising relaying the indication of the health status to the central server via the plurality of nodes in response to a magnitude of the electrical field generated by the electrical transmission line decreasing to a zero magnitude.

9. The method of claim 1, wherein the magnetometer is a three-dimensional magnetometer and the node is configured to measure a sag in the electrical transmission line based on analysis of the signal generated by the three-dimensional magnetometer.

10. A method for monitoring an electrical transmission line, comprising:
generating a signal with a magnetometer in response to receipt of an electrical field generated by the electrical transmission line with the magnetometer, wherein the magnetometer is included in a first node disposed at a first location located adjacent to the electrical transmission line;
detecting a change in magnitude of the electrical field, based on the signal;
relaying an indication of the change in magnitude of the electrical field to a central computing device via a second node that is disposed at a second location located adjacent to the electrical transmission line and down the electrical transmission line; and
analyzing the signal at the central computing device to determine a health status of the electrical transmission line.

11. The method of claim 10, further comprising generating a notification via the central computing device in response to the determination of the health status of the electrical transmission line.

12. The method of claim 11, further comprising broadcasting the notification to a plurality of mobile devices, wherein the notification includes an indication that the electrical transmission line is not operational and further includes a location of the first node.

13. The method of claim 10, wherein the magnetometer is at least one of a Hall Effect sensor and a MilliGaussian sensor.

14. The method of claim 10, further comprising tagging a position of each one of the nodes upon installation with an edge device.

15. The method of claim 10, further comprising broadcasting the indication of the change in magnitude of the electrical field to the second node and a third node from the first node, wherein the second node is disposed between the first node and the third node.

16. A system for monitoring an electrical transmission line, comprising:
a plurality of nodes disposed adjacent to and along the electrical transmission line, wherein each node includes a:
magnetometer configured to generate a signal in response to receipt of an electrical field generated by the electrical transmission line with the magnetometer;
a wireless communication interface configured to allow for communication between neighboring ones of the plurality of nodes; and
a processor and memory configured to analyze the signal in relation to a health status associated with the electrical transmission line; and
a central computing device configured to:
receive the health status from one of the plurality of nodes; and
generate a notification via the central computing device in response to the determination of the health status of the electrical transmission line.

17. The system of claim 16, wherein the system broadcasts the notification to mobile devices, wherein the notification includes an indication that the electrical transmission line is not operational and further includes a location of the first node.

18. The system of claim 16, wherein the plurality of nodes are disposed adjacent to and along the electrical transmission line for a mesh network.

19. The system of claim 16, wherein the wireless communication interface includes a long range radio.

20. The system of claim 16, wherein the health status associated with the electrical transmission line includes at least one of an indication of an operational status and a sag of the electrical transmission line.
